(19) United States
(12) Patent Application Publication
(10) Pub. No.: US 2012/0244695 A1
(43) Pub. Date: Sep. 27, 2012

(54) METHOD FOR FABRICATING FLASH MEMORY DEVICE AND FLOATING GATE THEREIN

(75) Inventors: XIANCHENG ZENG, Shanghai (CN); Shaobin Li, Shanghai (CN)

(73) Assignee: Semiconductor Manufacturing International (Shanghai Corporation), Shanghai (CN)

(21) Appl. No.: 13/216,240

(22) Filed: Aug. 24, 2011

(30) Foreign Application Priority Data
Mar. 22, 2011 (CN) 201110069308.8

(51) Int. Cl. H01L 21/28

(52) U.S. Cl. 438/593; 257/E21.209

(57) ABSTRACT

A method for fabricating a floating gate in a flash memory device includes providing a substrate, forming a first-type ion doped floating gate layer on the substrate, forming a first patterned photoresist layer on the first-type ion doped floating gate layer, dry etching the first patterned photoresist layer, wherein a dimension of the pattern of the first photoresist layer after the dry etching process is smaller than a dimension of the pattern before the dry etching process. The method further includes forming a dual-doped floating gate layer by implanting second-type ions into the first-type ion doped floating gate layer by using the first photoresist layer as a mask, wherein the first-type ions and the second-type ions have opposite charges. A flash memory device thus fabricated has a small CD and a dual-doped floating gate that provide high programming efficiency.

### CROSS-REFERENCES TO RELATED APPLICATIONS

The present application claims the priority of Chinese Patent Application No. 201110069308.8, entitled “Method for Fabricating Flash Memory Device and Floating Gate therein”, and filed on Mar. 22, 2011, the entire disclosure of which is incorporated herein by reference.

### FIELD OF THE INVENTION

The present invention relates generally to semiconductor technology, and more particularly to a method for fabricating flash memory device and floating gate therein.

### BACKGROUND OF THE INVENTION

Generally speaking, semiconductor memory devices are classified into volatile memory devices and non-volatile memory devices. Volatile memory devices tend to lose stored data when power is turned off, while non-volatile memory devices are able to retain stored data even when power is turned off.

Non-volatile memory devices include erasable programmable read only memory (EPROM) devices, electrically erasable programmable read only memory (EEPROM) devices, and flash memory devices. Compared with other non-volatile memory devices, flash memory devices have the characteristics of low power consumption, high degree of integration, high access speed, convenience to erase and rewrite, and low cost. As a result, flash memory devices are widely used in many applications, such as embedded systems, PCs and peripherals, telecommunication exchanges, cell phones, networking devices, digital audio devices, digital video devices, and data storage devices, digital cameras, and the like.

An elementary cell structure of a flash memory device contains a flash bit. The structure of a flash bit is different from the structure of a conventional metal-oxide-semiconductor (MOS) transistor. In a conventional MOS transistor, a gate is separated from a conductive channel by a gate insulation layer, which is normally an oxide layer whereas the flash bit has an additional floating gate (FG) disposed between a control gate, which is equivalent to the gate of a conventional MOS transistor, and a conductive channel. Due to the existence of the floating gate, the flash bit can have three modes of operations: read, write, and erase. Even when power is turned off, a flash bit can retain stored data owing to the floating gate. The adjacent flash memory bits are separated from each other by an isolation structure.

In prior art, a polysilicon floating gate of a flash memory device is usually mono-doped. For example, as for an n-type flash memory device, the polysilicon floating gate is n-type doped. At present, it has been set forth in some documents to improve performance of the flash memory device which is formed with a dual-doped floating gate.

However, the prior art publications do not disclose methods of fabricating a flash memory device which has both a dual-doped floating gate and a smaller critical dimension (CD). And a heat treating process is usually used to speed up the diffusion of doped ions during the fabrication of the dual-doped floating gate in the prior art, which causes a substantial increase in manufacturing cost. In addition, the flash memory device fabricated in the prior art has a low efficiency in programming and poor data retention characteristics.

Other technologies about the dual-doped floating gate have been described in the prior art, for example, a dual-doped floating gate is doped with P⁺N⁺P⁺ in the traverse direction, or comprises wide forbidden band material plus narrow forbidden band material plus wide forbidden band material.

### BRIEF SUMMARY OF THE INVENTION

Embodiments of the present invention provide solutions to the problems associated with the difficulty to fabricate a flash memory device having a dual-doped floating gate and a smaller critical dimension (CD) in the prior art, and that the conventional flash memory device has a low efficiency in programming, poor data retention characteristics, and high cost.

In one embodiment, a method for fabricating a floating gate in a flash memory device includes:

providing a substrate;

forming a floating gate layer on the substrate, the floating gate is doped with a first-type ions;

forming a first patterned photoresist layer on the first-type ion doped floating gate layer;

dry etching the first patterned photoresist layer, wherein a dimension of the pattern of the first photoresist layer after the dry etching process is smaller than a dimension of the pattern of the first photoresist layer before the dry etching process; and

forming a dual-doped floating gate layer by implanting second-type ions into the first-type ion doped floating gate layer by using the first photoresist layer after the dry etching process as a mask, wherein the first-type ions and the second-type ions have opposite charges.

Optionally, the gas used in dry etching comprises a mixed gas comprising CH₂F₂O₂ and HBr, in which a flow rate of CH₂F₂ is from about 2 sccm to about 50 sccm, a flow rate of O₂ is from about 2 sccm to about 100 sccm, a flow rate of HBr is from about 10 sccm to about 100 sccm.

Optionally, the dimension of the pattern of the first photoresist layer after the dry etching process is from about 45 to about 60 percent of the dimension of the pattern of the first photoresist layer before the dry etching process.

Optionally, the dual-doped floating gate is of a PNP structure.

Optionally, the first-type ions are N-type, and the second-type ions are P-type.

Optionally, the N-type ions are phosphorus. An implanting dosage of the N-type ions is from about 1.0 E14/cm³ to about 9.9 E20/cm³, and energy of the N-type ions is from about 5 keV to about 40 keV.

Optionally, the implanting dosage of the P-type ions is from about 10 to about 100 times of the implanting dosage of N-type ions. An energy of P-type ions is from about 8 keV to about 18 keV.

Optionally, the second-type ions are vertically implanted into the first-type ion doped floating gate layer by using the first photoresist layer after the dry etching process as a mask.

Optionally, the first-type ion doped floating gate layer is fabricated by an in-situ doping process.

In another embodiment, a method for fabricating a flash memory device which includes the above mentioned steps for fabricating the floating gate, further includes:

removing the first photoresist layer after the dry etching process and annealing the substrate after the dual-doped floating gate layer is formed;

forming a dielectric layer and a control gate layer in sequence on the dual-doped floating gate layer; and

etching the control gate layer, the dielectric layer and the floating gate layer till the substrate is exposed.

Optionally, the process of etching the control gate layer, the dielectric layer and the floating gate layer till the substrate exposed, includes:

forming a hard mask layer and a second patterned photoresist layer in sequence on the control gate layer;

etching the hard mask layer, the control gate layer, the dielectric layer and the floating gate layer till the substrate is exposed by using the second patterned photoresist layer as a mask; and

removing the second patterned photoresist layer and the hard mask layer.

Optionally, the floating gate layer and the control gate layer may include polycrystalline silicon or amorphous silicon.

Optionally, the temperature of annealing is from about 700° C. to about 1200° C.

Compared with the prior art, this invention has the following advantages:

The critical dimension (CD) of the flash memory device can be accurately controlled by dry etching the first patterned photoresist, which enables the flash memory device to have a smaller CD as required. On the other hand, due to the smaller dimension of the pattern of the first photoresist layer after the dry etching process than the dimension of the pattern of the first photoresist layer before the dry etching process, a diffusion region of the second-type ions is enlarged during the subsequent process of implanting the second-type ions. As a result, there is no need for heat treating process to diffuse the second-type ions, thereby reducing the manufacturing costs of flash memory devices.

A dual-doped floating gate can be made by first forming a floating gate then in-situ doping the floating gate with first-type ions, forming the first patterned photoresist layer over the doped floating gate; dry etching the first patterned photoresist layer; implanting second-type ions by using the first patterned photoresist layer after the dry etching process as a mask. A flash memory device having the dual-doped floating gate has a smaller CD. Moreover, the flash memory device thus fabricated has a high efficiency in programming and strong data retention capability.

### BRIEF DESCRIPTION OF THE DRAWINGS

FIG. 1 is a flow chart showing a method for fabricating a floating gate in a flash memory device, in accordance with one embodiment of the present invention;

FIG. 2 is a flow chart showing a method for fabricating a flash memory device, in accordance with another embodiment of the present invention; and

FIG. 3 to FIG. 12 are schematic cross-sectional views illustrating a method for fabricating a flash memory device shown in FIG. 2.

### DETAILED DESCRIPTION OF THE INVENTION

The present invention will be described in detail hereinafter with reference to the accompanying drawings, in which embodiments of the invention are shown.

The present invention can be implemented in many different forms and should not be construed as limited to the embodiments set forth herein.

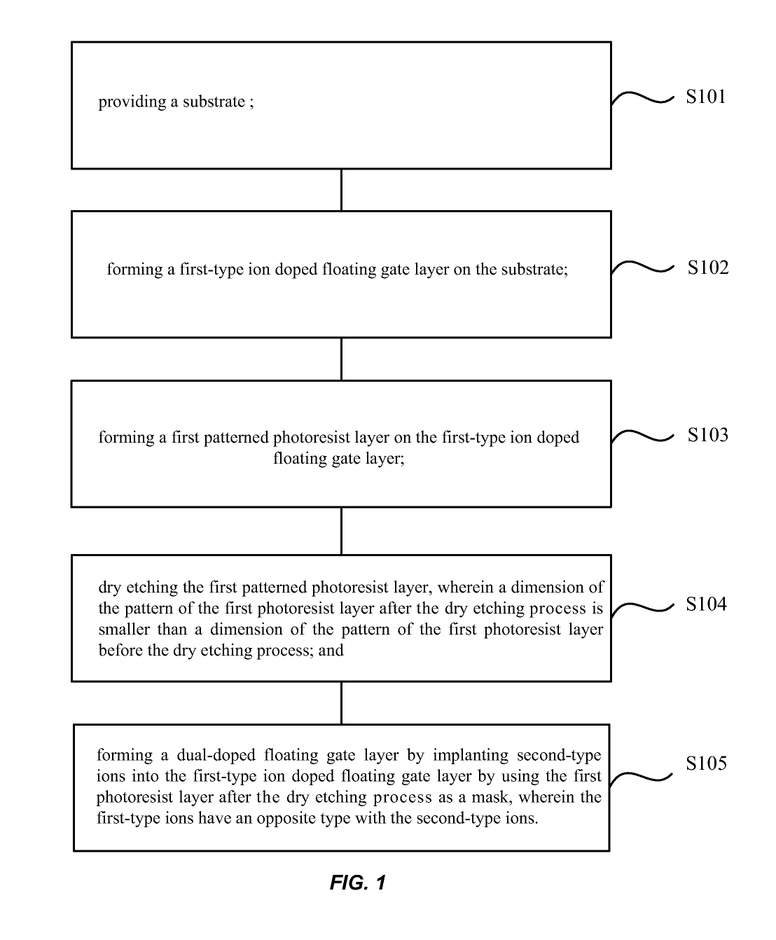

Referring to FIG. 1, which shows a flow chart of a method for fabricating a floating gate in a flash memory device, in accordance with one embodiment of the present invention, the method generally includes the following steps:

providing a substrate (S101);

forming a floating gate layer on the substrate, the floating gate layer is doped with a first type ion (S102);

forming a first patterned photoresist layer on the first-type ion doped floating gate layer (S103);

dry etching the first patterned photoresist layer, wherein a dimension of the pattern of the first photoresist layer after the dry etching process is smaller than a dimension of the pattern of the first photoresist layer before the dry etching process (S104);

forming a dual-doped floating gate layer by implanting second-type ions into the first-type ion doped floating gate layer by using the first photoresist layer after the dry etching process as a mask, wherein the first-type ions has an opposite type with the second-type ions (S105).

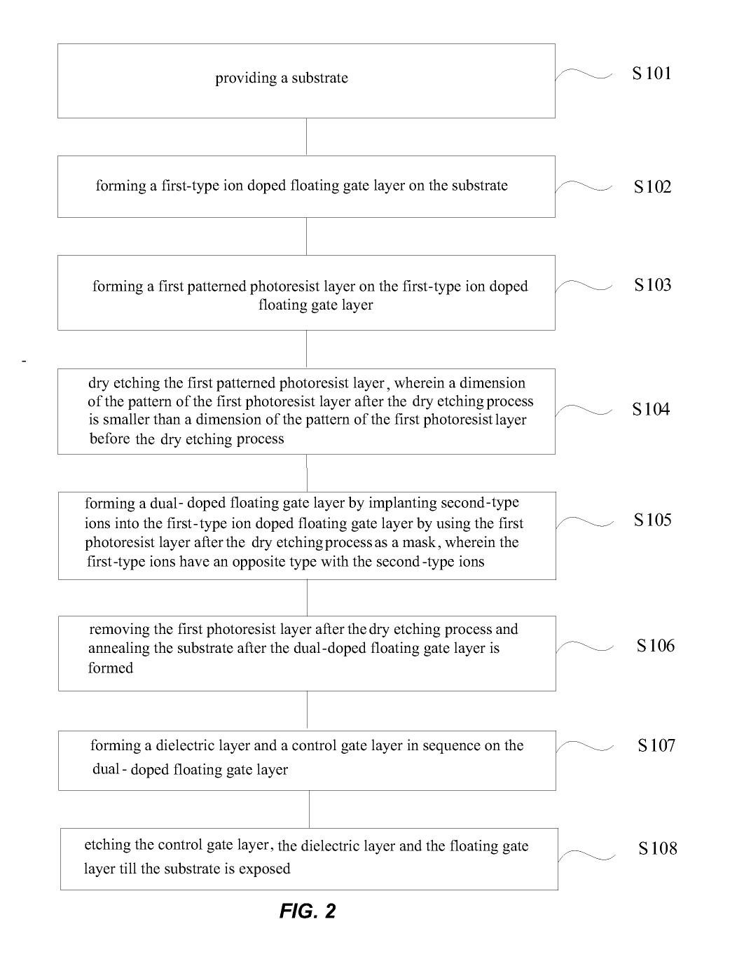

Referring to FIG. 2, which shows a flow chart of a method for fabricating a flash memory device, in accordance with another embodiment of the present invention, the method includes the following steps:

providing a substrate (S101);

forming a first-type ion doped floating gate layer on the substrate (S102);

forming a first patterned photoresist layer on the first-type ion doped floating gate layer (S103);

dry etching the first patterned photoresist layer, wherein a dimension of the pattern of the first photoresist layer after the dry etching process is smaller than a dimension of the pattern of the first photoresist layer before the dry etching process (S104);

forming a dual-doped floating gate layer by implanting second-type ions into the first-type ion doped floating gate layer by using the first photoresist layer after the dry etching process as a mask, wherein the first-type ions has an opposite type with the second-type ions (S105);

removing the first photoresist layer after the dry etching process and annealing the substrate after the dual-doped floating gate layer is formed (S106);

forming a dielectric layer and a control gate layer in sequence on the dual-doped floating gate layer (S107); and

etching the control gate layer, the dielectric layer and the floating gate layer until the substrate is exposed (S108).

The present invention will be described hereinafter in detail with reference to the accompanying drawings. In the following description, a PNP structure is used as an example, in which the first-type ions are N-type, and the second-type ions are P-type. In other embodiments, the first-type ions may be P-type, and the second-type ions may be N-type.

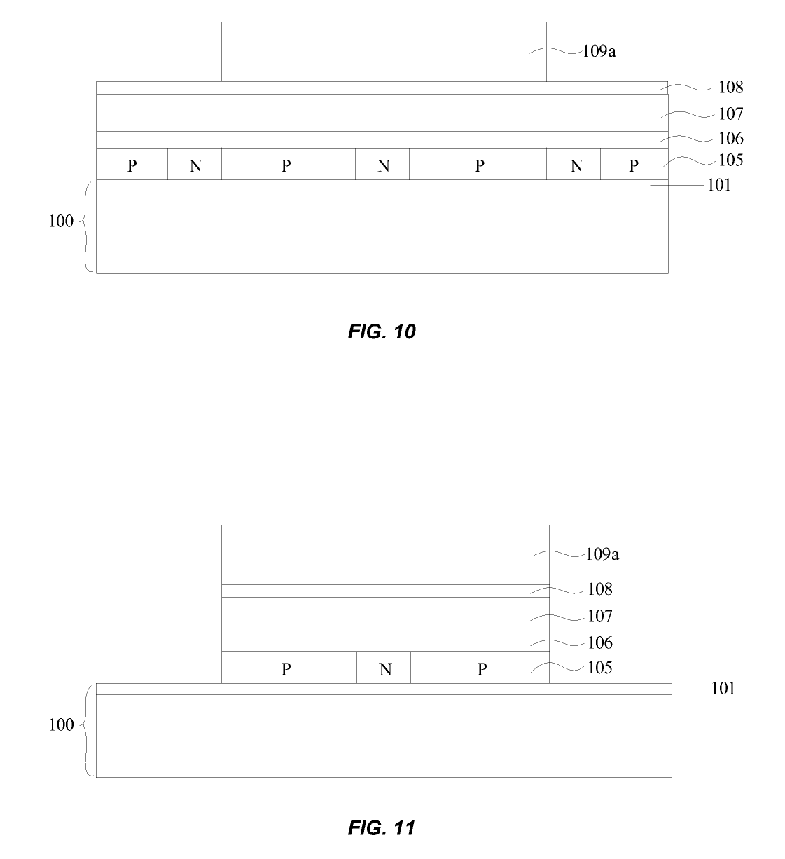

A method for fabricating a flash memory device of the present invention will now be described in detail with reference to FIG. 3 to FIG. 12.

First, a substrate 100 is provided, on which a first-type ion doped floating gate layer 102 is formed, as shown in FIG. 3 and steps S101 and S102.

In an embodiment, the substrate 100 may comprise monocrystal silicon, polycrystalline silicon or noncrystal silicon. In another embodiment, the substrate may comprise silicon, germanium, gallium arsenide, or silicon germanium compound, as well as other semiconductor materials. The substrate 100 may comprise an interconnecting layer, a dielectric layer, or STIs (not shown). The substrate 100 may have a tunneling oxide layer 101 formed thereon.

The tunneling oxide layer 101 according to an embodiment comprises silicon oxide. The process for forming the tunneling oxide layer 101 may be low pressure chemical vapor deposition (LPCVD), or thermal oxidation, and the like. In this embodiment, the tunneling oxide layer 101 is formed by LPCVD. The LPCVD process for forming the tunneling oxide layer 101 includes a gas containing silicon which may be SiH2Cl2 or SiH4, and a gas containing oxygen which may be O. Optionally, the LPCVD process may further include N2 as a dilute gas.

In a specific embodiment, the CVD process for forming the tunneling oxide layer 101 comprises the following parameters: a flow rate of the gas containing silicon and the gas containing oxygen from about 0.01 sccm to about 0.1 sccm, a flow rate of N2 from about 5 slm to about 50 slm, a temperature from about 800° C. to about 1100° C., a pressure from about 400 Torr to about 760 Torr, and a thickness of the tunneling oxide layer 101 from about 20 Å to about 100 Å.

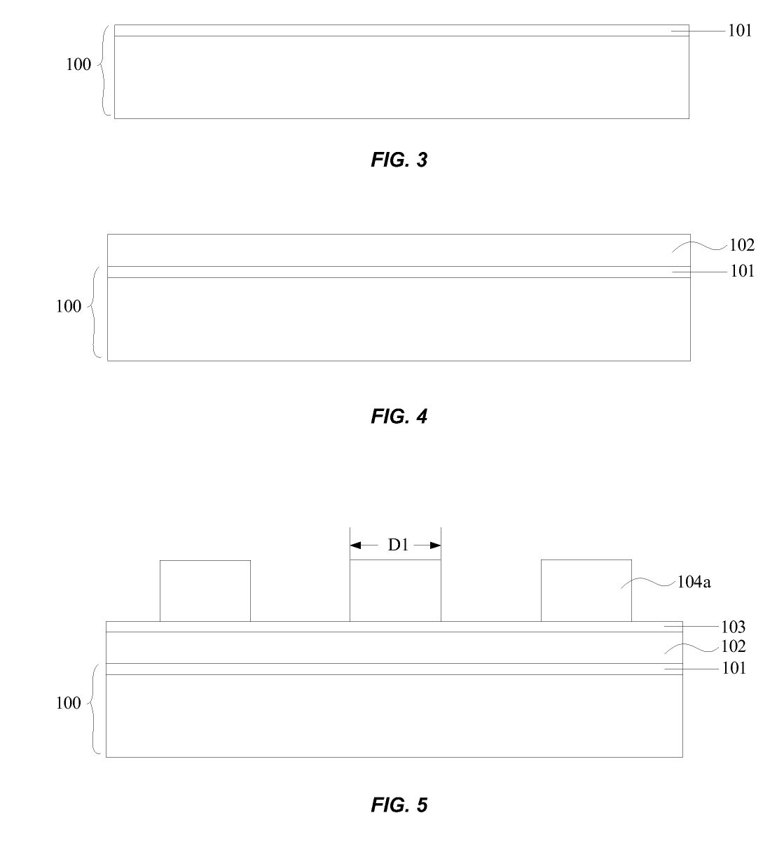

Referring to FIG. 4, an N-type ion doped floating gate layer 102 is formed on the tunneling oxide layer 101. The process for forming the N-type ion doped floating gate layer 102 may include depositing a floating gate layer first, then implanting N-type ions into the floating gate layer; or the process may include depositing a floating gate layer, while flowing a gas containing N-type ions. The N-type ions may be phosphorus ions, arsenic ions, and the like. The floating gate layer 102 may comprise amorphous silicon, or polycrystalline silicon. In a specific embodiment, the floating gate layer 102 comprises amorphous silicon, and the doped ions are phosphorus ions. The floating gate layer is formed by a low pressure chemical vapour deposition (LPCVD) process. Afterwards, the floating gate layer is doped with phosphorus ions in-situ.

In an embodiment, the process for forming the floating gate layer through the LPCVD process comprises the following parameters: a flow rate of SiH4 from about 200 sccm to about 400 sccm, a flow rate of N₂ from about 10 sccm to about 70 sccm, a temperature from about 500° C. to about 600° C., a pressure from about 0.2 Torr to about 0.3 Torr, and a thickness of the floating gate layer from about 500 Å to about 1500 Å. Then, phosphorus ions are implanted into the floating gate layer. An implanting dosage of the phosphorus ions is from about 1.0 E14/cm³ to about 9.9 E20/cm³, and an energy of the phosphorus ions is from about 5 keV to about 40 keV, so as to form the phosphorus ion doped floating gate layer 102.

Referring to FIG. 5, a first patterned photoresist layer 104a is formed on the first-type ion doped floating gate layer 102.

In an embodiment, before forming the first patterned photoresist layer 104a, a bottom anti-reflection layer 103 is formed on the phosphorus ion doped floating gate layer 102. The bottom anti-reflection layer 103 comprises SiN, which may be formed by a LPCVD process. Thereafter, a first photoresist layer is spin-on coated on the bottom anti-reflection layer 103, which is then exposed and developed to form the first patterned photoresist layer 104a. In an embodiment, the first patterned photoresist layer 104a has a dimension D1.

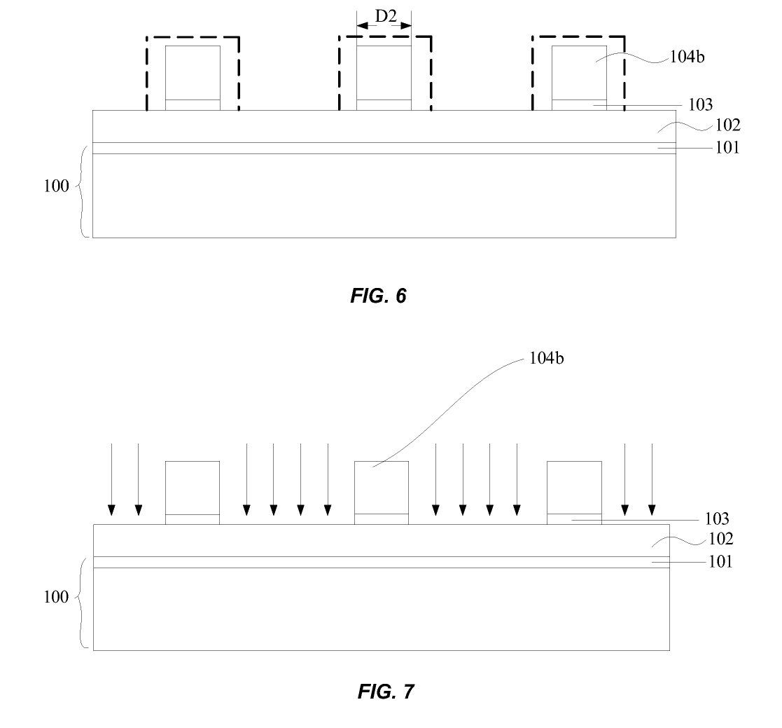

Referring to step S104 and FIG. 6, the first patterned photoresist layer 104a is dry etched. The pattern of the first photoresist layer 104b after the dry etching process has a dimension that is smaller than the dimension D1 of the pattern of the first photoresist layer 104a before the dry etching process. The dimension D1 of the pattern of the first photoresist layer that can be width, length, and thickness, is reduced by the dry etching process. Referring to FIG. 5 and FIG. 6, the form of the pattern of the first photoresist layer does not change substantially after the dry etching process in the step S104. The dry etching process narrows the width of the pattern.

In an embodiment, the dry etching process on the first patterned photoresist layer 104a and the bottom anti-reflection layer 103 is performed by flowing a mixed gas comprising CH₂F₂, O₂, and HBr at a radio frequency (RF) power from about 10 W to about 1000 W, in which the flow rate of CH2F2 is from about 2 sccm to about 50 sccm, the flow rate of O₂ is from about 2 sccm to about 100 sccm, and the flow rate of HBr is from about 10 sccm to about 100 sccm. In other words, the dimension D1 of the pattern of the first photoresist layer 104a is reduced by the dry etching process. In addition, a portion of the bottom anti-reflection layer 103 which is not located under the first patterned photoresist layer 104a is removed by the dry etching process.

In an embodiment, due to the dry etching process performed on the first patterned photoresist layer 104a, the critical dimension (CD) of a flash memory device to be fabricated can be accurately controlled, so that smaller CD of the flash memory device can be formed. On the other hand, because the dimension D2 of the pattern of the first photoresist layer 104b after the dry etching process is smaller than the dimension D1 of the pattern of the first photoresist layer 104a before the dry etching process, a diffusion region is enlarged into which P-type ions are implanted during subsequent processes. As a result, there is no need for a heat treating process to diffuse the P-type ions, and the costs associated with the heat treatment can be reduced or eliminated.

In addition, it should be noted that the pattern of the first photoresist layer 104b after the dry etching process should have a sufficient thickness so that the pattern of the first photoresist layer 104b would not be broken through in the subsequent process of implanting P-type ions into the N-type ion doped floating gate layer 102.

Moreover, the dimension D2 of the pattern of the first photoresist layer 104b after the dry etching process should not be too small, otherwise it would be difficult to fabricate a dual-doped floating gate having a PNP structure. In an embodiment, the dimension D1 of the pattern of the first photoresist layer 104a before the dry etching process is the channel length of the flash memory device, while the dimension D2 of the pattern of the first photoresist layer 104a after the dry etching process is from about 45 to 65 percent of the channel length of the flash memory device. The channel length of the flash memory device can be determined depending upon the fabrication processes.

Referring to step S105 and FIG. 7, a dual-doped floating gate layer is formed by implanting second-type ions into the first-type ion doped floating gate layer 102 by using the first photoresist layer 104b after the dry etching process as a mask, wherein the first-type ions and the second-type ions have opposite charges.

In an embodiment, a dual-doped floating gate layer having a PNP structure is formed by implanting P-type ions into the phosphorus ion doped floating gate layer 102 by using the first photoresist layer 104b after the dry etching process as a mask. The P-type ions may comprise boron ions, indium ions, and the like. In an embodiment, boron ions are used.

In a specific embodiment, boron ions are implanted vertically relative to the surface of the floating gate layer. An implanting dosage of the boron ions may be from about 10 to 100 times of the implanting dosage of phosphorus ions which are implanted into the floating gate layer. An implanting energy of the boron ions may be from about 8 keV to 18 keV. It is to be noted that in an embodiment, when the P-type ions implanted are boron ions, the implanting dosage of the boron ions may be from about 10 to 100 times of the implanting dosage of the phosphorus ions. And in other embodiments, the implanting dosage of the P-type ions may also be from about 10 to 100 times of the implanting dosage of the N-type ions. In the case where the first-type ions is P-type ions, and the second-type ions are N-type ions, the implanting dosage of the N-type ions may be from about 10 to 100 times of the implanting dosage of the P-type ions.

Up to now, the dual-doped floating gate layer, which has a PNP structure in this embodiment, is fabricated according to the above steps S101 to S105.

The present invention further provides another embodiment of a method for fabricating a flash memory device with the dual-doped floating gate layer formed therein.

Referring to step S106, as shown in FIG. 2, FIG. 7, and FIG. 8, after the dual-doped floating gate layer 105 is formed, the first photoresist layer 104b after the dry etching process is removed and the substrate 100 is annealed.

In an embodiment, an ashing process is used to remove the first photoresist layer 104b after the dry etching process. Afterwards, the photoresist residue after the ashing process together with the bottom anti-reflection layer 103 located under the first photoresist layer 104b after the dry etching process are removed by a wet etching process. To activate the doped ions in a crystal lattice, the substrate 100 is annealed. The annealing process may be performed at a temperature ranging from about 700° C. to about 1200° C., and with a time period ranging from about 5 s to about 120 s.

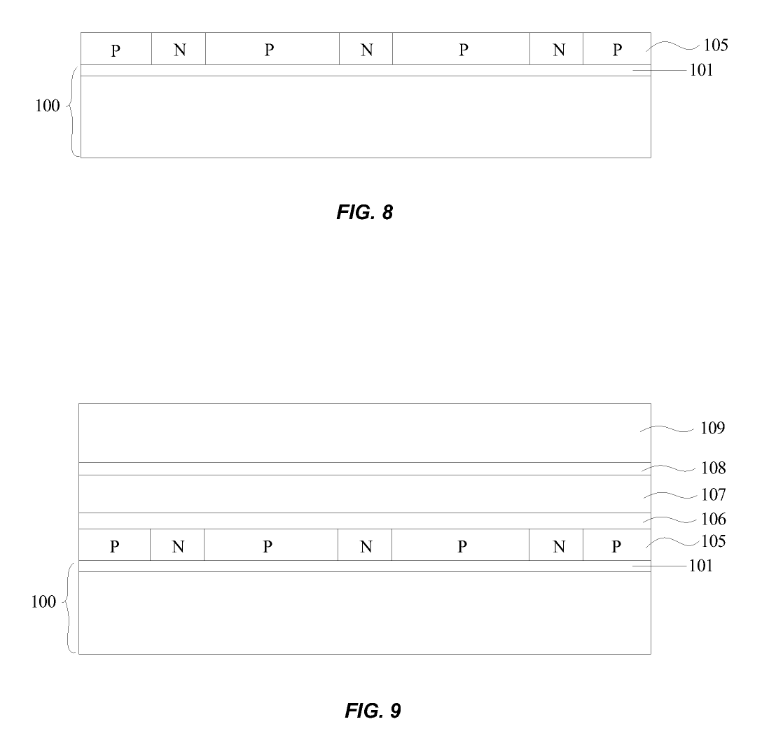

Referring to step S107 and FIG. 9, a dielectric layer 106 and a control gate layer 107 are subsequently formed on the dual-doped floating gate layer 105.

As shown in FIG. 9, the dielectric layer 106 and the control gate layer 107 are formed in sequence on the floating gate layer 105 having the PNP structure. In this embodiment, the dielectric layer 106 may have an ONO (silicon oxide-silicon nitride-silicon oxide) tri-layer structure, which has properties of low leakage current and defects when used as an insulating layer. The process of depositing silicon oxide may be chemical vapor deposition (CVD), plasma enhanced chemical vapor deposition (PECVD), and the like. The process of depositing silicon nitride may be PECVD, LPCVD, and the like. In an embodiment, the process of depositing silicon oxide is CVD, and the process of depositing silicon nitride is LPCVD.

The control gate layer 107 is deposited on the dielectric layer 106. In an embodiment, the control gate layer 107 is deposited by a LPCVD process, and comprises polycrystalline silicon. In an embodiment, the control gate layer 107 is doped with N-type or P-type ions after the control gate layer 107 is deposited, which reduces floating gate resistance.

Referring to step S108 and FIG. 11, the control gate layer 107, the dielectric layer 106 and the floating gate layer 105 are etched until the substrate 100 is exposed.

In an embodiment, the etch process may be dry etching, such as plasma etching or reaction ions etching (RIE). The process for etching the control gate layer 107, the dielectric layer 106 and the floating gate layer 105 until the substrate 100 is exposed, may include:

Sequentially forming a hard mask layer 108 and a second patterned photoresist layer 109a over the control gate layer 107. CVD may be used for forming the hard mask layer 108. The hard mask layer 108 may comprise SiN. Besides, the temperature required for depositing the hard mask layer 108 through the CVD process facilitates the diffusion of the P-type ions which are implanted into the N-type ion doped floating gate layer 102.

Referring to FIG. 9, the process for forming the second patterned photoresist layer 109a comprises forming a second photoresist layer 109 on the hard mask layer 108, and then exposing and developing the second photoresist layer 109 to form the second patterned photoresist layer 109a.

Now referring to FIG. 11, the hard mask layer 108, the control gate layer 107, the dielectric layer 106 and the floating gate layer 105 are etched until the substrate 100 is exposed by using the second patterned photoresist layer 109a as a mask.

In an embodiment, because the substrate 100 comprises a tunneling oxide layer 101, the hard mask layer 108, the control gate layer 107, the dielectric layer 106 and the floating gate layer having the PNP structure 105 are etched until the tunneling oxide layer 101 is exposed by using the second patterned photoresist layer 109a as a mask. The tunneling oxide layer 101 that is not etched may be used for forming other semiconductor devices. In some embodiments, the tunneling oxide layer 101 may be removed by an etching process.

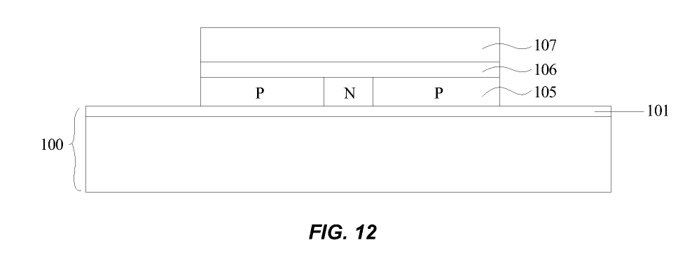

Finally, referring to FIG. 12, the second patterned photoresist layer 109a and the hard mask layer 108 are removed.

In an embodiment, the second patterned photoresist layer 109a is removed by using an ashing process. Afterwards, the photoresist residue and the hard mask layer 108 are removed by a wet etching process.

In addition, after forming the laminated structure shown in FIG. 12, the method further includes forming spacers and forming a flash memory device by performing a source/drain implantation beside the spacers, which are known in the prior art and thus not described herein.

In summary, embodiments of the present invention provide methods for fabricating a floating gate in a flash memory device. Due to the difference of carrier concentrations between P-region and N-region in the dual-doped floating gate, a PN junction is formed. A contact potential difference at the PN junction makes electrons generate additional static potential energy. The energy of electrons at the P-region is larger than the energy of electrons at the N-region, which prevents the electrons at the N-region from moving towards the P-region which causes an energy band bending of the floating gate in the transverse direction. In other words, the energy band of the P-region is higher than the energy band of the N-region. An energy band diagram comes into being, in which the energy band at both sides is higher, while the energy band in the middle is lower. The electrons are stored in an energy valley having lower energy band, therefore, the electrons are not likely to drop through a leakage path in the tunneling oxide layer in a source region or a drain region, which improves the efficiency in programming and data retention characteristic of the flash memory device.

In some embodiments of the invention, because the first patterned photoresist layer is processed by dry etching, the critical dimension (CD) of a flash memory device can be accurately controlled, so that the flash memory device has smaller CD than those made by conventional art. In addition, because the dimension of the pattern of the first photoresist layer after the dry etching process is smaller than the dimension of the pattern of the first photoresist layer before the dry etching process, the diffusion region of the second-type ions is enlarged during the subsequent process of implanting the second-type ions. Moreover, a heat treating process to diffuse the second-type ions is not required, so that the manufacturing costs can be reduced.

In other embodiments of the present invention, the method for fabricating a dual-doped floating gate can include forming an N-type ion doped floating gate layer first, forming a first patterned photoresist layer, dry etching the first patterned photoresist layer, and implanting P-type ions by using the first patterned photoresist layer after the dry etching process as a mask. A flash memory device having the dual-doped floating gate has a smaller CD, and the cost for fabricating the flash memory device is low.

Although the present invention has been disclosed above with reference to preferred embodiments thereof, it should be understood that the invention is presented by way of example only, and not limitation. Those skilled in the art can modify and vary the embodiments without departing from the spirit and scope of the present invention.

What is claimed is:

1. A method for fabricating a floating gate in a flash memory device, the method comprising:
providing a substrate;
forming a floating gate layer on the substrate, the floating gate being doped with first-type ions;
forming a first patterned photoresist layer on the first-type ion doped floating gate layer;
dry etching the first patterned photoresist layer, wherein a dimension of the pattern of the first photoresist layer after the dry etching process is smaller than a dimension of the pattern of the first photoresist layer before the dry etching process; and
forming a dual-doped floating gate layer by implanting second-type ions into the first-type ion doped floating gate layer by using the first photoresist layer after the dry etching process as a mask, wherein the first-type ions and the second-type ions have opposite charges.

2. The method according to claim 1, wherein dry etching comprises a mixed gas comprising CH₂F₂, O₂ and HBr, wherein a flow rate of CH₂F₂ is from about 2 sccm to about 50 sccm, a flow rate of O₂ is from about 2 sccm to about 100 sccm, and a flow rate of HBr is from about 10 sccm to about 100 sccm.

3. The method according to claim 1, wherein the dimension of the pattern of the first photoresist layer after the dry etching process is from about 45 to about 60 percent of the dimension of the pattern of the first photoresist layer before the dry etching process.

4. The method according to claim 1, wherein the dual-doped floating gate comprises a PNP structure.

5. The method according to claim 1, wherein the first-type ions are N-type, and the second-type ions are P-type.

6. The method according to claim 1, wherein the first-type ions are phosphorus ions having an implanting dosage ranging from about 1.0 E14/cm³ to about 9.9 E20/cm³ and an energy ranging from about 5 keV to about 40 keV.

7. The method according to claim 1, wherein implanting the second-type ions comprises a dosage ranging from about 10 to about 100 times of an implanting dosage of the first-type ions, and an energy ranging from about 8 keV to about 18 keV.

8. The method according to claim 1, wherein the second-type ions are vertically implanted into the first-type ion doped floating gate layer by using the first photoresist layer after the dry etching process as a mask.

9. The method according to claim 1, wherein the first-type ion doped floating gate layer is formed by an in-situ doping process.

10. A method for fabricating a flash memory device, comprising:
providing a substrate;
forming a first-type ion doped floating gate layer on the substrate;
forming a first patterned photoresist layer on the first-type ion doped floating gate layer;
dry etching the first patterned photoresist layer, wherein a dimension of the pattern of the first photoresist layer after the dry etching process is smaller than a dimension of the pattern of the first photoresist layer before the dry etching process;
forming a dual-doped floating gate layer by implanting second-type ions into the first-type ion doped floating gate layer by using the first photoresist layer after the dry etching process as a mask, wherein the first-type ions and the second-type ions have opposite charges;
removing the first photoresist layer after the dry etching process;
annealing the substrate after the dual-doped floating gate layer is formed;
forming a dielectric layer and a control gate layer in sequence on the dual-doped floating gate layer; and
etching the control gate layer, the dielectric layer and the floating gate layer until the substrate is exposed.

11. The method according to claim 10, wherein the dry etching comprises a mixed gas comprising CH₂F₂, O₂ and HBr, wherein a flow rate of CH₂F₂ is from about 2 sccm to about 50 sccm, a flow rate of O₂ is from about 2 sccm to about 100 sccm, and a flow rate of HBr is from about 10 sccm to about 100 sccm.

12. The method according to claim 10, wherein the dimension of the pattern of the first photoresist layer after the dry etching process is from about 45 to about 60 percent of the dimension of the pattern of the first photoresist layer before the dry etching process.

13. The method according to claim 10, wherein the dual-doped floating gate comprises a PNP structure.

14. The method according to claim 10, wherein the first-type ions are N-type, and the second-type ions are P-type.

15. The method according to claim 10, wherein the first-type ions are phosphorus ions having an implanting dosage ranging from about 1.0 E14/cm³ to about 9.9 E20/cm³ and an energy ranging from about 5 keV to about 40 keV.

16. The method according to claim 10, wherein implanting the second-type ions comprises a dosage ranging from about 10 to about 100 times of an implanting dosage of first-type ions and an energy ranging from about 8 keV to about 18 keV.

17. The method according to claim 10, wherein the second-type ions are vertically implanted into the first-type ion doped floating gate layer by using the first photoresist layer after the dry etching process as a mask.

18. The method according to claim 10, wherein the first-type ion doped floating gate layer is formed by an in-situ doping process.

19. The method according to claim 10, wherein etching the control gate layer, the dielectric layer and the floating gate layer comprises:
sequentially forming a hard mask layer and a second patterned photoresist layer over the control gate layer;
etching the hard mask layer, the control gate layer, the dielectric layer and the floating gate layer until the substrate is exposed by using the second patterned photoresist layer as a mask; and
removing the second patterned photoresist layer and the hard mask layer.

20. The method according to claim 10, wherein the floating gate layer and the control gate layer comprise polycrystalline silicon or amorphous silicon.

21. The method according to claim 10, wherein the annealing is performed at a temperature from about 700° C. to about 1200° C.
